(19) United States
(12) Patent Application Publication
(10) Pub. No.: US 2014/0054066 A1
(43) Pub. Date: Feb. 27, 2014

(54) CIRCUIT LAYOUT METHOD AND ASSOCIATED PRINTED CIRCUIT BOARD

(71) Applicant: MStar Semiconductor, Inc., Hsinchu Hsien (TW)

(72) Inventors: Tien Hua Yu, Hsinchu Hsien (TW); Shih Wei Lin, Hsinchu Hsien (TW)

(73) Assignee: MStar Semiconductor, Inc., Hsinchu Hsien (TW)

(21) Appl. No.: 13/956,478

(22) Filed: Aug. 1, 2013

Related U.S. Application Data
(60) Provisional application No. 61/691,276, filed on Aug. 21, 2012.

(51) Int. Cl. H05K 1/02; G06F 17/50

(52) U.S. Cl. CPC H05K 1/0213; G06F 17/5068
USPC 174/250; 716/137

(57) ABSTRACT

A circuit layout method for a printed circuit board (PCB) is provided. The method includes forming a pair of signal traces on the PCB, and disposing a ground trace between the pair of signal traces. The pair of signal traces and the ground trace are located at a same layer of the PCB, and the ground trace renders the pair of transmission traces to have predetermined impedance. An associated PCB is also provided. The PCB includes a circuit layer, and a ground layer for grounding. The circuit layer includes a pair of signal traces, and a ground grace disposed between the pair of signal traces. The circuit layer is different from the ground layer. Based on the circuit layout method and the associated PCB, an electronic apparatus not only complies with mobile high-definition link (MHL) requirements regarding impedance between signal traces but also offers reduced costs.

This application claims the benefit of U.S. Provisional Patent Application 61/691,276, filed Aug. 21, 2012, the subject matter of which is incorporated herein by reference.

### BACKGROUND OF THE INVENTION

1. Field of the Invention

The invention relates in general to signal quality control having economic cost considerations, and more particularly to a circuit layout method and an associated printed circuit board (PCB) which improves signal quality control while reducing cost of electronic device manufacturing.

2. Description of the Related Art

Electronic circuit techniques are currently quite mature, and many publications as references of modern signal processing methods for enhancing signal quality are also readily available. However, in actual situations, signal quality control of conventional electronic circuits may still be further improved under strict material cost control considerations.

According to associated techniques, certain issues are frequently incurred by imposing strict controls on material costs of a main circuit architecture of an electronic apparatus during a design phase. For example, signal processing components for enhancing signal quality may be insufficient, meaning that expected signal quality is not achieved, or a signal transmission speed of the electronic apparatus is limited. For another example, when selecting a two-layer printed circuit board (PCB) from conventional PCBs for a main circuit architecture of an electronic apparatus, signal transmission quality of the electronic apparatus may be unsatisfactory or unstable. Therefore, there is a need for a solution for enhancing signal quality control in electronic devices having significant economic cost considerations.

### SUMMARY OF THE INVENTION

It is an object of the present invention to provide a circuit layout method and an associated printed circuit board (PCB) for solving the abovementioned issues.

It is another object of the present invention to provide a circuit layout method and an associated PCB capable of achieving high signal quality in a low cost device.

A circuit layout method is provided according to a preferred embodiment of the present invention. The circuit layout method comprises forming a pair of signal traces on the PCB, and disposing a ground trace between the pair of signal traces. The pair of signal traces and the ground traces are located at a same layer of the PCB, and the ground trace renders the pair of signal traces to have predetermined impedance.

A PCB is further provided according to another preferred embodiment of the present invention. The PCB comprises: a circuit layer, comprising a pair of signal traces, and a ground trace disposed between the pair of signal traces; and a ground layer for grounding. The circuit layer is different from the ground layer. More particularly, the ground trace renders the pair of signal traces to have predetermined impedance.

With the circuit layout method and the associated PCB according to the embodiments of the present invention, material costs of an electronic apparatus can be effectively reduced without sacrificing signal quality. Further, the circuit layout method and the associated PCB according to the embodiments of the present invention also enhance signal quality control under economic cost considerations.

The above and other aspects of the invention will become better understood with regard to the following detailed description of the preferred but non-limiting embodiments. The following description is made with reference to the accompanying drawings.

### BRIEF DESCRIPTION OF THE DRAWINGS

FIG. 1 is a schematic diagram of an electronic apparatus according to an embodiment of the present invention.

FIG. 2 is a flowchart of a circuit layout method according to an embodiment of the present invention.

FIG. 3 shows a PCB associated with the circuit layout method in FIG. 2 according to an embodiment of the present invention.

FIG. 4 shows a PCB associated with the circuit layout method in FIG. 2 according to another embodiment of the present invention.

FIG. 5 shows a layout control solution associated with the circuit layout method in FIG. 2 according to an embodiment of the present invention.

FIG. 6 shows measured results of differential impedance associated with the circuit layout method in FIG. 2 according to an embodiment of the present invention.

FIG. 7 shows measured results of common mode impedance associated with the circuit layout method in FIG. 2 according to another embodiment of the present invention.

FIG. 8 shows simulation results associated with the circuit layout method in FIG. 2 according to an embodiment of the present invention.

### DETAILED DESCRIPTION OF THE INVENTION

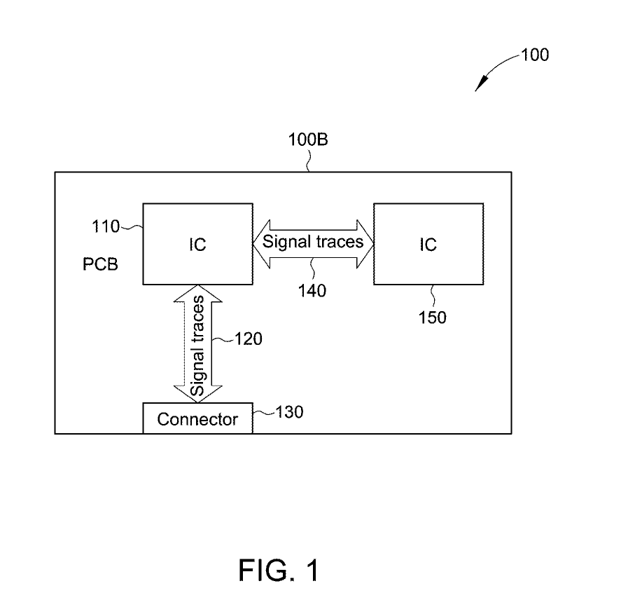

FIG. 1 shows a schematic diagram of an electronic apparatus 100 according to an embodiment of the present invention. The electronic apparatus 100 may comprise a printed circuit board (PCB) 100B, and various components, e.g., integrated circuits 110 and 150, disposed on the PCB 100B, and a connector 130. The PCB 100B may comprise at least one group of signal traces such as a first group of signal traces 120 and a second group of signal traces 140. The first group of signal traces 120 are disposed between the integrated circuit 110 and the connector 130, and the second group signal traces 140 are disposed between the integrated circuits 110 and 150. The above arrangement is an exemplary illustration for the present invention rather than a limitation to the present invention. In an alternative embodiment, the at least one of the two groups of signal traces may include an additional group of traces, with the additional group of signal traces disposed between two connectors. In one embodiment, the number of the integrated circuits on the PCB 100B may be other than two. For example, the PCB 100B may be disposed with one integrated circuit such as the integrated circuit 110, and does not include the second group of signal traces 140. For another example, the PCB 100B may be disposed with more than three integrated circuits.

For simplification purposes, other components such as a housing of the electronic apparatus 100 are not depicted in FIG. 1. It should be noted that, this is an exemplary illustration for the present invention rather than a limitation to the present invention. Alternatively, the electronic apparatus 100 may comprise the above housing (not shown), and other modules such as a camera module, a display module (e.g., a liquid-crystal display (LCD) and/or a touch panel), a user input module (e.g., buttons, a touch screen, and/or touch screen), and an audio output module (e.g., a speaker and/or headphone jacks).

In common practice, for example, the above integrated circuit, such as the integrated circuits 110 and 150, may include various processors (for example, microprocessors), and various controllers (for example, display controllers and/or monitor controllers).

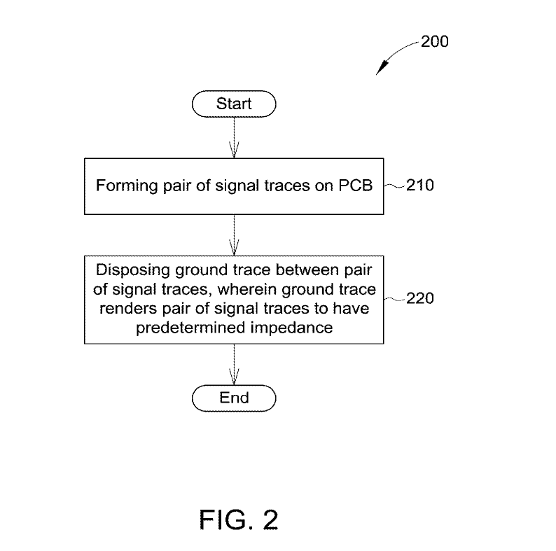

FIG. 2 shows a flowchart of a circuit layout method 200 according to an embodiment of the present invention. The method is applicable to the electronic apparatus 100 in FIG. 1, and more particular to the PCB 100B in FIG. 1. The circuit layout method 200 comprises the following steps.

In step 210, a pair of signal traces are formed on the PCB 100B. More specifically, the PCB 100B comprises a circuit layer, which comprises the pair of signal traces. For example, the pair of signal traces may be a pair of signal traces from the above first group of signal traces 120, or maybe a pair of signal traces from the above second group of signal traces 140. It should be noted that the above details are exemplary illustrations for the present invention rather than limitations to the present invention. In other embodiments, the pair of signal traces may represent a pair of signal traces from the additional group of signal traces between the two connectors.

In step 220, a ground trace is disposed between the pair of signal traces. The ground trace renders the pair of signal traces to have predetermined impedance. For example, the predetermined impedance is differential impedance or common mode traces of the pair of signal traces. In the embodiment, the PCB 100B further comprises a ground layer for grounding. The circuit layer is different from the ground layer. It should be noted that, the ground trace is disposed between the pair of signal traces, and the pair of signal traces are disposed at the circuit layer, such that the ground trace is disposed at the circuit layer.

In practice, the ground trace is electrically connected to the ground layer. For example, the PCB 100B may further comprise a metal connector via for electrically connecting the ground trace to the ground layer. In another example, the ground trace is connected to a pin of an integrated circuit with the pin providing a ground signal. The pair of signal traces and the ground trace are located at the same layer (the circuit layer in the embodiment) of the PCB 100B, and the layer for disposing the pair of the signal traces and the ground trace is different from the ground layer.

In the embodiment, the pair of signal traces may be a pair of differential signal traces for transmitting a pair of differential signals. More particularly, the signal traces are for transmitting a pair of mobile high-definition link (MHL) signals. Further, the predetermined impedance (e.g., the differential impedance or the common mode impedance of the pair of signal traces) in step 220 complies with MHL specifications. For example, when the predetermined impedance is either of the differential impedance and the common mode impedance, the differential impedance and the common mode impedance both comply with MHL specifications. Further, the circuit layout method 200 may limit a width of the ground trace, a width of a gap between any of the pair of signal traces and the ground trace, and/or a width of any of the pair of signal traces to achieve optimal signal quality control effects. For example, according to a first limitation, the width of the ground trace is within a range of 3 Mil (1/1000 of an inch) to 7 Mil. Alternatively, according to a second limitation, the width of the gap between any of the pair of signal traces and the ground trace is within a range of 2 Mil to 6 Mil. Alternatively, according to the third limitation, the width of any of the pair of signal traces is within a range of 10 Mil to 14 Mil. Alternatively, according to at least a part (all or a part) of the first limitation, the second limitation, and the third limitation, the above corresponding widths are all limited.

According to the embodiment, the detail of forming the pair of signal traces on the PCB 100B in step 210 is given as an example. In another embodiment, the circuit layout method 200 may further comprise forming an additional signal trace on the PCB 100B, and disposing an additional ground trace between the pair of signal traces and the additional signal trace. The additional ground trace renders the predetermined impedance between the pair of signal traces and the additional signal trace.

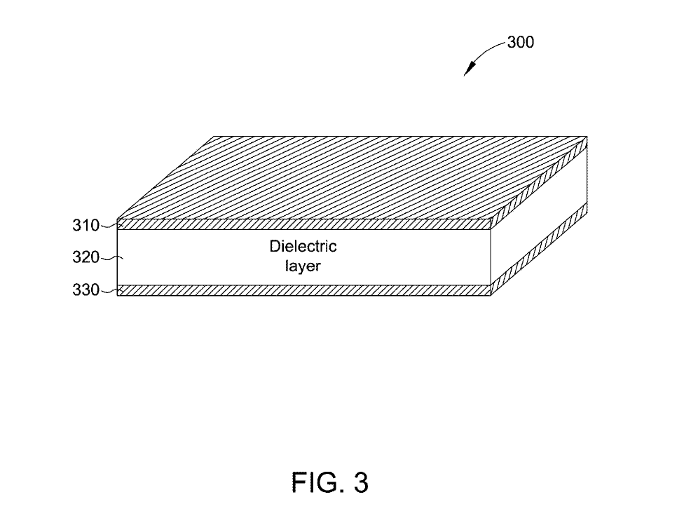

FIG. 3 shows a PCB 300 associated with the circuit layout method 200 in FIG. 2 according to an embodiment of the present invention. The PCB 300 is an example of the PCB 100B in FIG. 1. For simplification purposes, certain components of the PCB 300 are not depicted in FIG. 3.

As shown in FIG. 3, the PCB 300 comprises a plurality of layers such as conductive layers 310 and 330. For example, the circuit layer where the pair of signal traces are located as described in step 210 may be the conductive layer 310, and the foregoing ground layer may be the other conductive layer 330. For another example, the circuit layer where the pair of signal traces are located as described in step 210 may be the conductive layer 330, and the foregoing ground layer may be the other conductive layer 310. Further, a dielectric layer 320 is disposed between the conductive layers 310 and 330. As there are two conductive layers in the PCB 300, the PCB 300 is regarded as a two-layer PCB.

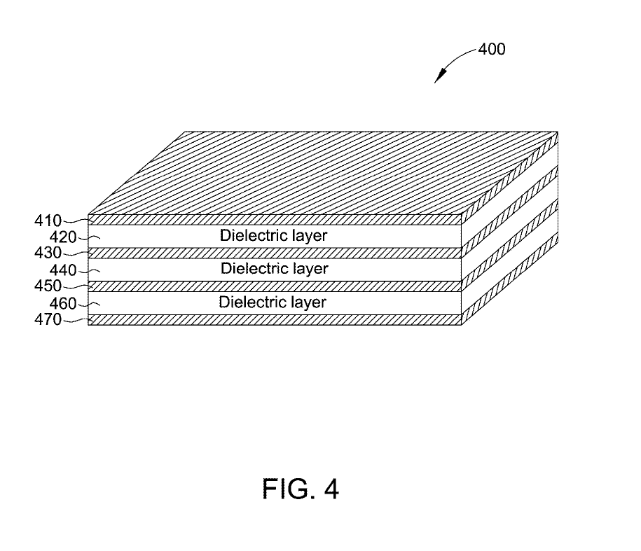

FIG. 4 shows a PCB 400 associated with the circuit layout method 200 in FIG. 2 according to an embodiment of the present invention. The PCB 400 is an example of the PCB 100B in FIG. 1. For simplification purposes, certain components of the PCB 400 are not depicted in FIG. 4.

As shown in FIG. 4, the PCB 400 comprises a plurality of conductive layers 410, 430, 450, and 470. For example, the circuit layer where the pair of signal traces are located as described in step 210 may be the conductive layer 410, and the foregoing ground layer may be any of the conductive layers 430, 450, and 470. For another example, the circuit layer where the pair of signal traces are located as described in step 210 may be the conductive layer 470, and the foregoing ground layer may be any of the conductive layers 410, 430, and 450. Further, dielectric layers 420, 440, and 460 are respectively disposed between the conductive layers 410, 430, 450, and 470. That is, between every two neighboring conductive layers (e.g., the two conductive layers 410 and 430, the two conductive layers 430 and 450, or the two conductive layers 450 and 470) of the conductive layers 410, 430, 450, and 470 is a corresponding dielectric layer. As there are four conductive layers in the PCB 400, the PCB 400 may be regarded as a four-layer PCB.

It should be noted that the two-layer PCB and the four-layer PCB in FIGS. 3 and 4 are examples of the PCB 100B in FIG. 1, and are for illustrating rather than limiting the present invention. In other embodiments modified from the embodiments in FIGS. 3 and 4, a PCB having different number of conductive layers may also be regarded as an example of the PCB 100B in FIG. 1.

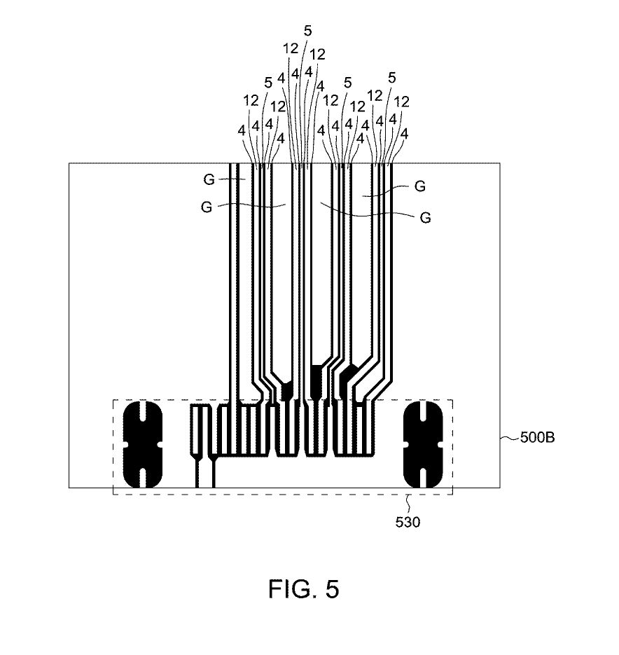

FIG. 5 shows a layout control solution associated with the circuit layout method 200 in FIG. 2. A PCB 500B is regarded as an example of the PCB 100B in FIG. 1. On the PCB 500B, a region 530 corresponding to the connector 130 comprises a plurality of terminals, which may be implemented as a common pattern such as goldfingers in the prior art. For simplification purposes, certain components of the PCB 500B are not depicted in FIG. 5.

As shown in FIG. 5, the PCB 500B comprises a plurality of signal traces 12, a plurality of ground traces 5, and a plurality of ground regions G. A gap 4 is present between any two neighboring parts (e.g., one ground region G and one signal trace 12 that are neighboring to each other, one signal trace 12 and one ground trace 5 that are neighboring to each other, one ground trace 5 and one signal grace 12 that are neighboring to each other, or one signal trace 12 and one ground region G that are neighboring to each other) of the signal traces 12, the ground traces 5, and the ground regions G. According to the embodiment, a width of each of the signal traces 12 may be 12 Mil, a width of each of the ground traces 5 may be 5 Mil, and a width of each of the gaps 4 may be 4 Mil. The above values for the widths are for illustrating rather than limiting the present invention, and may be modified in other embodiments. For example, in another embodiment, the width of each of the signal traces 12 may be within a range of 10 Mil to 14 Mil (i.e., intervals [(12−2), (12+2)]), the width of each of the ground traces 5 may be within a range of 3 Mil to 7 Mil (i.e., intervals [(5−2), (5+2)], and the width of each of the gaps 4 may be within a range of 2 Mil to 6 Mil (i.e., intervals [(4−2), (4+2)].

In practice, for example, the black regions may represent etched parts in the circuit layer, i.e., the parts of removed conductive materials from the conductive layer. In other embodiments, the black regions in FIG. 5 may represent parts without conductive materials in the circuit layer, i.e., the parts without formation in the conductive layer.

It should be noted that, the region 530 of the PCB 500B in this embodiment corresponds to the connector 130 in FIG. 1, and so the pair of signal traces 12 shown in FIG. 5 may be regarded as an example of the first group of signal traces 120. In an alternative embodiment of the present invention, the layout control solution in FIG. 5 does not limit the circuit layout of the signal traces between the integrated circuit 110 and the connector 130. For example, the lower part of FIG. 5 may be replaced by a group of pin soldering points, such as a soldering point of any of certain pins of the integrated circuits 110 and 150, and the pair of signal traces 12 in FIG. 5 may be regarded as an example of the second group of signal traces 140. For another example, the region 530 in FIG. 5 may be regarded as a region corresponding to another connector (e.g., either of the two abovementioned connectors), and the pair of signal traces 12 in FIG. 5 may be regarded as an example of the abovementioned additional group of signal traces.

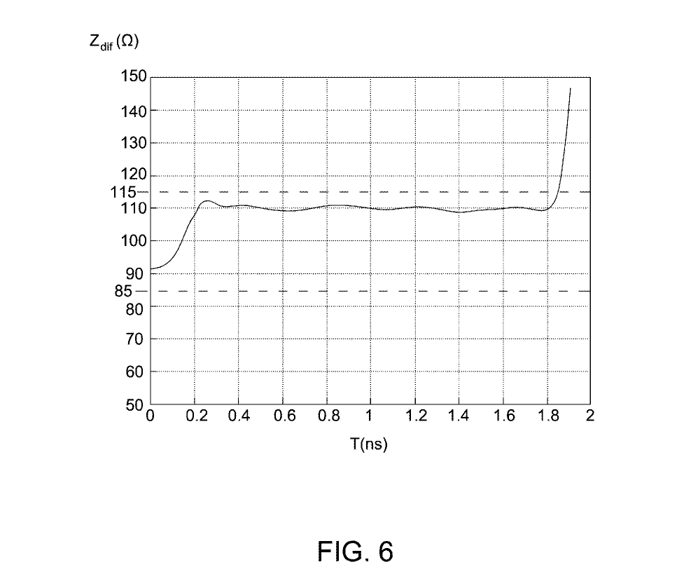

FIG. 6 shows measured results of the differential impedance associated with the circuit layout method 200 in FIG. 2 according to an embodiment of the present invention. As shown in FIG. 6, the horizontal axis T represents time in a unit of nanoseconds (ns), and the vertical axis Zdif represents the differential impedance of the pair of signal traces in a unit of ohms (Ω).

As previously stated, the ground trace renders the signal traces to have the predetermined impedance. In the embodiment, the predetermined impedance may be the differential impedance, which falls within an interval [(100−15), (100+15)], i.e., a range [85, 115], in a unit of ohms (Ω). According to the embodiment, based on the circuit layout method 200 in FIG. 2, the electronic apparatus 100 complies with MHL specifications. More particularly, the differential impedance of the pair of signal traces in step 210 complies with MHL specifications.

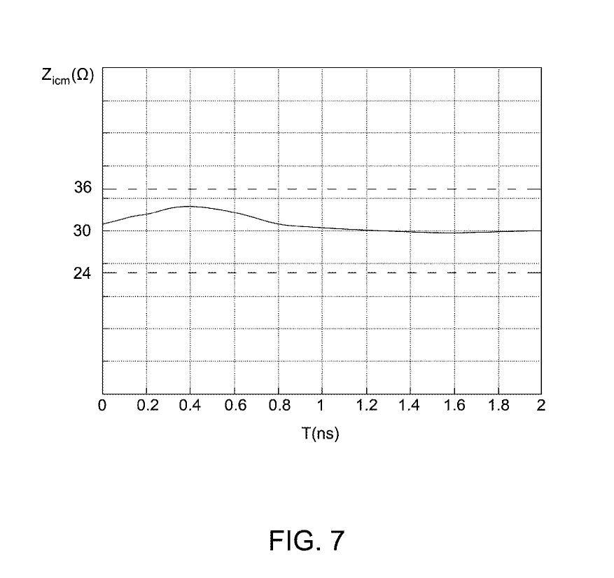

FIG. 7 shows measured results of the common mode impedance associated with the circuit layout method 200 in FIG. 2. As shown in FIG. 7, the horizontal axis T represents time in a unit of nanoseconds (ns), and the vertical axis Zicm represents the common mode impedance of the pair of signal traces, in a unit of ohms (Ω).

As previously stated, the ground trace renders the pair of signal traces to have the predetermined impedance value. In the embodiment, the predetermined impedance may be the common mode impedance, which falls within an interval [(30−6), (30+6)], i.e., a range [24, 36], in a unit of ohms (Ω). According to the embodiment, based on the circuit layout method 200 in FIG. 2, the electronic apparatus 100 complies with MHL specifications. More particularly, the common mode impedance of the pair of signal traces in step 210 complies with MHL specifications.

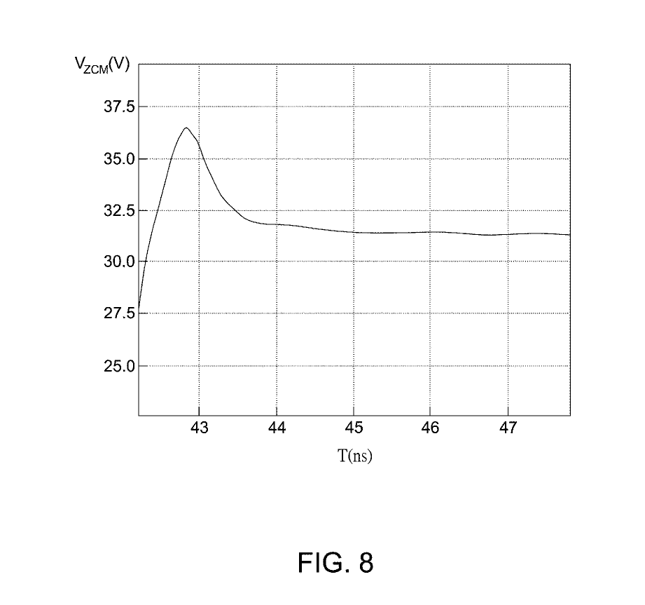

FIG. 8 shows simulation results associated with the circuit layout method 200 in FIG. 2 according to an embodiment of the present invention. As shown in FIG. 8, the horizontal axis T represents time in a unit of nanoseconds (ns), and the vertical axis V_{ZCM} represents a voltage corresponding to the common mode impedance, in a unit of volts (V).

It should be noted that, from at least a part of the embodiments in FIGS. 6, 7 and 8, based on the circuit layout method 200 in FIG. 2, the electronic apparatus 100 complies with MHL specifications.

With the circuit layout method and the associated PCB according to the embodiments of the present invention, material costs of an electronic apparatus can be effectively reduced without sacrificing signal quality. Further, the circuit layout method and the associated PCB according to the embodiments of the present invention also enhance signal quality control under economic cost considerations.

While the invention has been described by way of example and in terms of the preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A circuit layout method, for a printed circuit board (PCB), comprising:
forming a pair of signal traces on the PCB; and
disposing a ground trace between the pair of signal traces;
wherein, the pair of signal traces and the ground trace are located at a same layer of the PCB, and the ground trace renders the pair of signal traces to have predetermined impedance.

2. The circuit layout method according to claim 1, wherein the PCB comprises a ground layer, and the layer for disposing the pair of signal traces and the ground trace is different from the ground layer.

3. The circuit layout method according to claim 1, wherein the pair of signal traces are a pair of differential signal traces for transmitting a pair of differential signals.

4. The circuit layout method according to claim 1, further comprising:
forming one other signal trace on the PCB; and
disposing one other ground trace between the pair of signal traces and the other signal trace;
wherein, the other ground trace renders the predetermined impedance between the pair of signal traces and the other signal trace.

5. The circuit layout method according to claim 1, wherein the pair of signal traces are configured for transmitting a pair of Mobile High-Definition Link (MHL) signals.

6. The circuit layout method according to claim 1, wherein a width of the ground trace is between 3 Mil and 7 l Mil.

7. The circuit layout method according to claim 1, wherein a width of a gap between any of the pair of signal traces and the ground trace is between 2 Mil and 6 Mil.

8. The circuit layout method according to claim 1, wherein a width of any of the pair of signal traces is between 10 Mil and 14 Mil.

9. The circuit layout method according to claim 1, wherein differential impedance and common mode impedance of the pair of signal traces comply with MHL specifications.

10. A printed circuit board (PCB), comprising:
a circuit layer, comprising:
a pair of signal traces; and
a ground trace, disposed between the pair of signal traces; and
a ground layer, for grounding;
wherein, the circuit layer is different from the ground layer.

11. The PCB according to claim 10, wherein the ground trace renders the pair of signal traces to have predetermined impedance.

12. The PCB according to claim 10, wherein the pair of signal traces are a pair of differential signal traces for transmitting a pair of differential signals.

13. The PCB according to claim 10, wherein the circuit layer further comprises:
one other signal trace; and
one other ground trace, disposed between the pair of signal traces and the other signal trace;
wherein, the other ground trace renders the predetermined impedance between the pair of signal traces and the other signal trace.

14. The PCB according to claim 10, wherein the pair of signal traces are for transmitting a pair of MHL signals.

15. The PCB according to claim 10, wherein a width of the ground trace is between 3 Mil and 7 Mil.

16. The PCB according to claim 10, wherein a width of a gap between any of the pair of signal traces and the ground trace is between 2 Mil and 6 Mil.

17. The PCB according to claim 10, wherein a width of any of the pair of signal traces is between 10 Mil and 14 Mil.

18. The PCB according to claim 10, wherein differential impedance and common mode impedance of the pair of signal traces comply with MHL specifications.
